(19) United States
(12) Patent Application Publication
(10) Pub. No.: US 2026/0103796 A1
(43) Pub. Date: Apr. 16, 2026

(54) MULTILAYER COATINGS FOR REDUCED SURFACE METALS ON OXIDE FILMS

(71) Applicant: ENTEGRIS, INC., Billerica, MA (US)

(72) Inventors: Gavin Richards, Kent, NY (US); Bryan C. Hendrix, Danbury, CT (US); Rong Zhao, Newtown, CT (US)

(21) Appl. No.: 19/358,334

(22) Filed: Oct. 14, 2025

Related U.S. Application Data
(60) Provisional application No. 63/707,368, filed on Oct. 15, 2024.

(51) Int. Cl. C23C 16/40

(52) U.S. Cl. CPC C23C 16/403; C23C 16/401

(57) ABSTRACT

Components comprising multilayer coatings for reducing surface metals and related methods of producing multilayer coatings are disclosed. A coating comprises an oxide layer and an aluminum oxide layer. The aluminum oxide layer is different than the oxide layer. The oxide layer is located between a component and the aluminum oxide layer. When measured using Secondary Ion Mass Spectrometry (SIMS), the oxide layer and the aluminum oxide layer reduce a concentration of an impurity in the aluminum oxide layer by at least 10% compared to a control coating without the oxide layer.

### FIELD

The present disclosure relates to multilayer coatings for reducing surface metals on oxide films.

### BACKGROUND

Substrates made from alloys are used during semiconductor fabrication. These substrates contain trace metals and other contaminants that can cause defects in downstream components.

### SUMMARY

Some embodiments relate to a coating. In some embodiments, the coating comprises an oxide layer. In some embodiments, the coating comprises an aluminum oxide layer. In some embodiments, the aluminum oxide layer is different than the oxide layer. In some embodiments, the oxide layer is located between a component and the aluminum oxide layer. In some embodiments, when measured using Secondary Ion Mass Spectrometry (SIMS), the oxide layer and the aluminum oxide layer reduce a concentration of an impurity in the aluminum oxide layer by at least 10% compared to a control coating without the oxide layer.

Some embodiments relate to a method. In some embodiments, the method comprises obtaining a component. In some embodiments, the method comprises exposing the component to at least a first precursor to form an oxide layer on a surface of the component. In some embodiments, the method comprises exposing the oxide layer to at least an aluminum precursor and a coreactant to form an aluminum oxide layer on the oxide layer. In some embodiments, the aluminum oxide layer is different than the oxide layer. In some embodiments, when measured using Secondary Ion Mass Spectrometry (SIMS), the oxide layer and the aluminum oxide layer reduce a concentration of an impurity in the aluminum oxide layer by at least 10% compared to a control without the oxide layer.

Some embodiments relate to a coating. In some embodiments, the coating comprises an inner aluminum oxide layer. In some embodiments, the coating comprises a composite. In some embodiments, the composite comprises a first oxide layer and a second oxide layer. In some embodiments, the second oxide layer is different than the first oxide layer. In some embodiments, the second oxide layer is located on the first oxide layer. In some embodiments, the first oxide layer is located on the inner aluminum oxide layer. In some embodiments, the coating comprises an outer aluminum oxide layer. In some embodiments, the outer aluminum oxide layer is located on the composite. In some embodiments, the inner aluminum oxide layer is located between a component and the composite. In some embodiments, when measured using Secondary Ion Mass Spectrometry (SIMS), the composite reduces a concentration of an impurity in the outer aluminum oxide layer by at least 10% compared to a control coating without the composite.

Some embodiments relate to a method. In some embodiments, the method comprises form an inner aluminum oxide layer on a component. In some embodiments, the method comprises forming a composite on the inner aluminum oxide layer. In some embodiments, the composite comprises a first layer comprising a silicon oxide. In some embodiments, the composite comprises a second layer comprising an aluminum oxide. In some embodiments, the first layer is located between the inner aluminum oxide layer and the second layer. In some embodiments, the method comprises forming an outer aluminum oxide layer on the composite. In some embodiments, when measured using Secondary Ion Mass Spectrometry (SIMS), the composite reduce a concentration of an impurity in the outer aluminum oxide layer by at least 10% compared to a control without the composite.

### BRIEF DESCRIPTION OF THE DRAWINGS

FIG. 1 is a schematic diagram of a cross-section of a coating, according to some embodiments.

FIG. 2 is a flowchart of a method of producing multilayer coatings, according to some embodiments.

FIG. 3 is a schematic diagram of a vessel assembly, according to some embodiments.

FIG. 4 is a Secondary Ion Mass Spectrometry (SIMS) showing the concentration of an impurity (Mg) along a depth in a comparative example.

FIG. 5 is a schematic diagram of a cross-section of a coating on a component, according to some embodiments.

FIG. 6 is a Secondary Ion Mass Spectrometry (SIMS) showing the concentration of an impurity (Mg) along a depth, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure are intended to be illustrative and are not restrictive.

Some embodiments relate to a coating. In some embodiments, the coating comprises an oxide layer. In some embodiments, the oxide layer can comprise a silicon oxide. In some embodiments, the oxide layer comprises a silicon dioxide of the formula: SiₓO_{y}, where x is 1 to 2 and y is 1.8 to 2.5. In some embodiments, the oxide layer has a thickness of 10 Å to 100 Å, or any range or subrange between 10 Å and 100 Å. In some embodiments, the oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the coating comprises an aluminum oxide layer. In some embodiments, the aluminum oxide layer is different than the oxide layer. In some embodiments, the aluminum oxide layer comprises an aluminum oxide of the formula: Al₂O_{y}, where y is 2.5 to 3.5. In some embodiments, the aluminum oxide layer has a thickness of 10 Å to 100 Å, or any range or subrange between 10 Å and 100 Å. In some embodiments, the aluminum oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the oxide layer is located between a component and the aluminum oxide layer. In some embodiments, the component comprises a substrate, a vessel, a tray, a cabinet, a conduit, an ampoule, a chamber, a pipe, a valve, or any combination thereof. In some embodiments, the component comprises an aluminum alloy, a nickel alloy, a stainless steel, a cobalt alloy, a titanium alloy, or any combination thereof. In some embodiments, the component comprises at least one of iron, chromium, nickel, cobalt, molybdenum, manganese, vanadium, niobium, magnesium, titanium, copper, zinc, lead, aluminum, tin, or any combination thereof.

In some embodiments, when measured using Secondary Ion Mass Spectrometry (SIMS), the oxide layer and the aluminum oxide layer reduce a concentration of an impurity in the aluminum oxide layer by at least 10% compared to a control coating without the oxide layer. In some embodiments, the oxide layer and the aluminum oxide layer reduce a concentration of an impurity in the aluminum oxide layer by at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 100% compared to a control coating without the oxide layer.

In some embodiments, the impurity comprises at least one of iron, chromium, nickel, cobalt, molybdenum, manganese, vanadium, niobium, magnesium, titanium, copper, zinc, lead, aluminum, tin, or any combination thereof. In some embodiments, the impurity in the aluminum oxide layer comes from the component.

In some embodiments, the coating comprises an aluminum oxide layer located between the component and the oxide layer. In some embodiments, the aluminum oxide layer located between the component and the oxide layer comprises an aluminum oxide of the formula: Al₂O_{y}, where y is 2.5 to 3.5. In some embodiments, the aluminum oxide layer located between the component and the oxide layer has a thickness of 10 Å to 100 Å, or any range or subrange between 10 Å and 100 Å. In some embodiments, the aluminum oxide layer located between the component and the oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the coating comprises the oxide layer and the aluminum oxide layer. In some embodiments, the coating comprises an inner aluminum oxide layer, an oxide layer, and an outer aluminum oxide layer. In some embodiments, the coating comprises 2 to 1000 layers, 2 to 900 layers, 2 to 800 layers, 2 to 700 layers, 2 to 600 layers, 2 to 500 layers, 2 to 400 layers, 2 to 300 layers, 2 to 200 layers, 2 to 100 layers, 2 to 90 layers, 2 to 80 layers, 2 to 70 layers, 2 to 60 layers, 2 to 50 layers, 2 to 40 layers, 2 to 30 layers, 2 to 20 layers, 2 to 10 layers, 2 to 8 layers, 2 to 6 layers, 2 to 4 layers, 4 to 1000 layers, 6 to 1000 layers, 8 to 1000 layers, 10 to 1000 layers, 20 to 1000 layers, 30 to 1000 layers, 40 to 1000 layers, 50 to 1000 layers, 60 to 1000 layers, 70 to 1000 layers, 80 to 1000 layers, 90 to 1000 layers, 100 to 1000 layers, 200 to 1000 layers, 300 to 1000 layers, 400 to 1000 layers, 500 to 1000 layers, 600 to 1000 layers, 700 to 1000 layers, 800 to 1000 layers, or 900 to 1000 layers. In some embodiments, the layers of the coating alternate between being an oxide layer, such as a silicon oxide layer, and an aluminum oxide layer.

In some embodiments, when measured using Secondary Ion Mass Spectrometry (SIMS), the concentration of an impurity in the aluminum oxide layer is 10 times to 1000 times, or any range or subrange between 10 times to 1000 times, less than the concentration of the impurity in the aluminum oxide layer of a control coating, wherein the control coating does not comprise the oxide layer. In some embodiments, the concentration of the impurity in the aluminum oxide layer is 10 times to 900 times, 10 times to 800 times, 10 times to 700 times, 10 times to 600 times, 10 times to 500 times, 10 times to 400 times, 10 times to 300 times, 10 times to 200 times, 10 times to 100 times, 10 times to 90 times, 10 times to 80 times, 10 times to 70 times, 10 times to 60 times, 10 times to 50 times, 10 times to 40 times, 10 times to 30 times, 10 times to 20 times, 20 times to 1000 times, 30 times to 1000 times, 40 times to 1000 times, 50 times to 1000 times, 60 times to 1000 times, 70 times to 1000 times, 80 times to 1000 times, 90 times to 1000 times, 100 times to 1000 times, 200 times to 1000 times, 300 times to 1000 times, 400 times to 1000 times, 500 times to 1000 times, 600 times to 1000 times, 700 times to 1000 times, 800 times to 1000 times, or 900 times to 1000 times less than the concentration of the impurity in the aluminum oxide layer a control component, wherein the control component does not comprise the oxide layer.

In some embodiments, alternatively to using SIMS, Auger Electron Spectroscopy (AES), X-ray Photoelectron Spectroscopy (XPS), Scanning Electron Microscopy (SEM), Electron Probe Microanalysis (EPMA), Rutherford Backscattering Spectrometry (RBS), Elastic Recoil Detection (ERD), Particle-Induced X-ray Emission (PIXE), Laser Ablation Inductively Coupled Plasma Mass Spectrometry (LA-ICP-MS), Glow Discharge Optical Emission Spectroscopy (GD-OES), or Laser-Induced Breakdown Spectroscopy (LIBS) can be used.

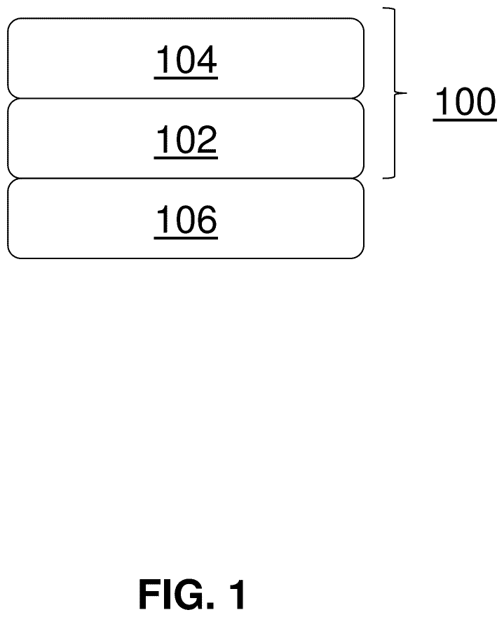

FIG. 1 is a schematic diagram of a cross-section of a coating, according to some embodiments. The coating 100 includes an oxide layer 102 and an aluminum oxide layer. The oxide layer 102 is located between a component 106 and the aluminum oxide layer 104.

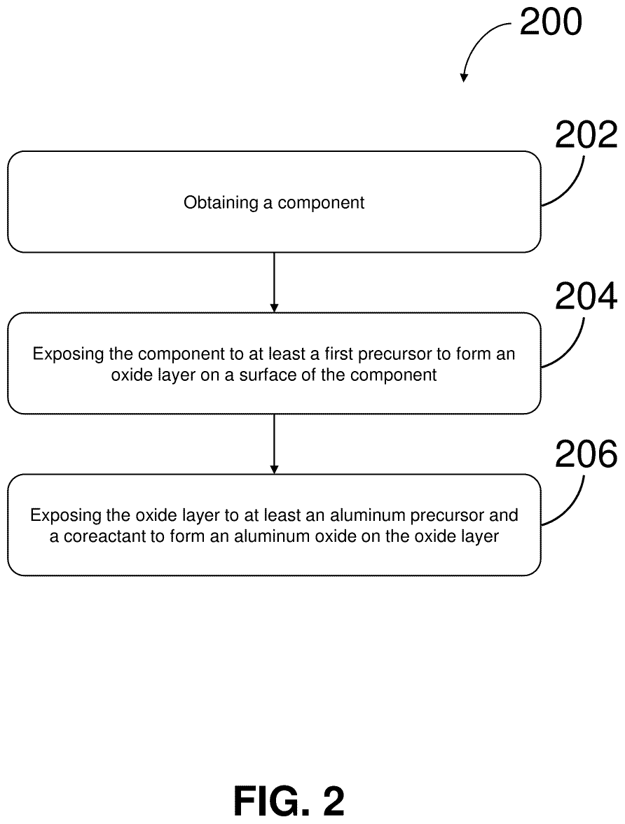

FIG. 2 is a flowchart for the method 200 of producing multilayer coatings, according to some embodiments. The method 200 can include obtaining a component 202, exposing the component to at least a first precursor to form an oxide layer on a surface of the component 204, and exposing the oxide layer to at least an aluminum precursor and a coreactant to form an aluminum oxide layer on the oxide layer 206.

At step 202, in some embodiments, the method comprises obtaining a component. In some embodiments, the component comprises a substrate, a vessel, a tray, a cabinet, a conduit, an ampoule, a chamber, a pipe, a valve, or any combination thereof. In some embodiments, the component comprises an aluminum alloy, a nickel alloy, a stainless steel, a cobalt alloy, a titanium alloy, or any combination thereof. In some embodiments, the component comprises at least one of iron, chromium, nickel, cobalt, molybdenum, manganese, vanadium, niobium, magnesium, titanium, copper, zinc, lead, aluminum, tin, or any combination thereof.

At step 204, in some embodiments, the method comprises exposing the component to at least a first precursor to form an oxide layer on a surface of the component. In some embodiments, exposing comprises bringing at least the first precursor in close or direct contact with the component. In some embodiments, exposing comprises flowing a vapor of at least the first precursor across the component. In some embodiments, exposing comprises a deposition process. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the first precursor is a silicon precursor and the oxide layer is a silicon oxide layer. In some embodiments, the silicon precursor comprises at least one of a tris(methoxy)silanol, a tris(ethoxy)silanol, a tris(tert-butoxy)silanol, a tris(tert-pentoxy)silanol, a bis(tert-butylamino)silane, a bis(diethylamino)silane, a bis(trichlorosilyl)ethane, a di(isopropylamino)silane, a tetraethyl orthosilicate, a silicon tetrachloride, a tris(dimethylamino)silane, a hexachlorodisilane, or any combination thereof.

In some embodiments, the component is exposed to the first precursor at a temperature of 25° C. to 500° C., or any range or subrange between 25° C. to 500° C., and for a pulse duration of 0.1 second (s) to 500 s, or any range or subrange between 0.1 s to 500 s, to form the oxide layer. In some embodiments the component is exposed to the first precursor at a temperature of 25° C. to 500° C., 25° C. to 400° C., 25° C. to 300° C., 25° C. to 200° C., 25° C. to 100° C., 25° C. to 90° C., 25° C. to 80° C., 25° C. to 70° C., 25° C. to 60° C., 25° C. to 50° C., 25° C. to 40° C., 25° C. to 30° C., 30° C. to 500° C., 40° C. to 500° C., 50° C. to 500° C., 60° C. to 500° C., 70° C. to 500° C., 80° C. to 500° C., 90° C. to 500° C., 100° C. to 500° C., 200° C. to 500° C., 300° C. to 500° C., or 400° C. to 500° C. In some embodiments, the substrate or the inner layer, if present, is exposed for a pulse duration of 0.1 s to 400 s, 0.1 s to 300 s, 0.1 s to 200 s, 0.1 s to 100 s, 0.1 s to 90 s, 0.1 s to 80 s, 0.1 s to 70 s, 0.1 s to 60 s, 0.1 s to 50 s, 0.1 s to 40 s, 0.1 s to 30 s, 0.1 s to 20 s, 0.1 s to 10 s, 0.1 s to 5 s, 0.1 s to 1 s, 0.1 s to 0.9 s, 0.1 s to 0.8 s, 0.1 s to 0.7 s, 0.1 s to 0.6 s, 0.1 s to 0.5 s, 0.1 s to 0.4 s, 0.1 s to 0.3 s, 0.1 s to 0.2 s, 0.2 s to 500 s, 0.3 s to 500 s, 0.4 s to 500 s, 0.5 s to 500 s, 0.6 s to 500 s, 0.7 s to 500 s, 0.8 s to 500 s, 0.9 s to 500 s, 1 s to 500 s, 5 s to 500 s, 10 s to 500 s, 20 s to 500 s, 30 s to 500 s, 40 s to 500 s, 50 s to 500 s, 60 s to 500 s, 70 s to 500 s, 80 s to 500 s, 90 s to 500 s, 100 s to 500 s, 200 s to 500 s, 300 s to 500 s, or 400 s to 500 s.

At step 206, in some embodiments, the method comprises exposing the oxide layer to at least an aluminum precursor and a coreactant to form an aluminum oxide on the oxide layer. In some embodiments, exposing comprises bringing at least the aluminum precursor and the coreactant in close or direct contact with the oxide layer. In some embodiments, exposing comprises flowing a vapor of at least the aluminum precursor and the coreactant across the oxide layer. In some embodiments, exposing comprises a deposition process. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. In some embodiments, exposing comprises simultaneously flowing an aluminum precursor and a coreactant. In some embodiments, exposing comprises alternating pulses of an aluminum precursor and a coreactant.

In some embodiments, the aluminum precursor comprises at least one of a trimethyl aluminum (TMA), a triethyl aluminum (TEA), a triisobutylaluminum (TIBA), a diethylaluminum chloride (DEAC), a methylaluminooxane (MAO), a dimethylaluminum isopropoxide (DMAI), an aluminum trichloride (AlCl₃), or any combination thereof.

In some embodiments, the coreactant comprises water, O₂, O₃, or any combination thereof.

In some embodiments, the oxide layer is exposed to at least the aluminum precursor and the coreactant at a temperature of 25° C. to 500° C., or any range or subrange between 25° C. to 500° C., and for a pulse duration of 0.1 seconds (s) to 5 s, or any range or subrange between 0.1 s to 5 s. In some embodiments, the oxide layer is exposed to at least the aluminum precursor and the coreactant at a temperature of 25° C. to 500° C., 25° C. to 400° C., 25° C. to 300° C., 25° C. to 200° C., 25° C. to 100° C., 25° C. to 90° C., 25° C. to 80° C., 25° C. to 70° C., 25° C. to 60° C., 25° C. to 50° C., 25° C. to 40° C., 25° C. to 30° C., 30° C. to 500° C., 40° C. to 500° C., 50° C. to 500° C., 60° C. to 500° C., 70° C. to 500° C., 80° C. to 500° C., 90° C. to 500° C., 100° C. to 500° C., 200° C. to 500° C., 300° C. to 500° C., or 400° C. to 500° C. In some embodiments, the oxide layer is exposed for a pulse duration of 0.1 s to 4 s, 0.1 s to 3 s, 0.1 s to 2 s, 0.1 s to 1 s, 0.1 s to 0.9 s, 0.1 s to 0.8 s, 0.1 s to 0.7 s, 0.1 s to 0.6 s, 0.1 s to 0.5 s, 0.1 s to 0.4 s, 0.1 s to 0.3 s, 0.1 s to 0.2 s, 0.2 s to 5 s, 0.3 s to 5 s, 0.4 s to 5 s, 0.5 s to 5 s, 0.6 s to 5 s, 0.7 s to 5 s, 0.8 s to 5 s, 0.9 s to 5 s, 1 s to 5 s, 2 s to 5 s, 3 s to 5 s, or 4 s to 5 s.

In some embodiments, when measured using Secondary Ion Mass Spectrometry (SIMS), the oxide layer and the aluminum oxide layer reduce a concentration of an impurity in the aluminum oxide layer by at least 10% compared to a control without the oxide layer. In some embodiments, the oxide layer and the aluminum oxide layer reduce a concentration of an impurity in the aluminum oxide layer by at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 100% compared to a control without the oxide layer.

In some embodiments, the impurity comprises at least one of iron, chromium, nickel, cobalt, molybdenum, manganese, vanadium, niobium, magnesium, titanium, copper, zinc, lead, aluminum, tin, or any combination thereof. In some embodiments, the impurity in the aluminum oxide layer comes from the component.

In some embodiments, before forming the oxide layer, the component is exposed to at least an aluminum precursor and a coreactant to form an inner aluminum oxide layer. In some embodiments, the inner aluminum oxide layer is exposed to at least the first precursor to from the oxide layer thereupon. In some embodiments, the coreactant comprises water, O₂, O₃, or any combination thereof. In some embodiments, the inner aluminum oxide layer is formed by simultaneously flowing an aluminum precursor and a coreactant. In some embodiments, the inner aluminum oxide layer is formed by alternating pulses of an aluminum precursor and a coreactant.

In some embodiments, the aluminum oxide precursor comprises at least one of a trimethyl aluminum (TMA), a triethyl aluminum (TEA), a triisobutylaluminum (TIBA), a diethylaluminum chloride (DEAC), a methylaluminooxane (MAO), a dimethylaluminum isopropoxide (DMAI), an aluminum trichloride (AlCl₃), or any combination thereof.

In some embodiments, the component is exposed to the aluminum precursor and the coreactant at a temperature of 25° C. to 500° C., or any range or subrange between 25° C. to 500° C., and for a pulse duration of 0.1 seconds (s) to 5 s, or any range or subrange between 0.1 s to 5 s. In some embodiments, the component is exposed to the aluminum precursor and the coreactant at a temperature of 25° C. to 500° C., 25° C. to 400° C., 25° C. to 300° C., 25° C. to 200° C., 25° C. to 100° C., 25° C. to 90° C., 25° C. to 80° C., 25° C. to 70° C., 25° C. to 60° C., 25° C. to 50° C., 25° C. to 40° C., 25° C. to 30° C., 30° C. to 500° C., 40° C. to 500° C., 50° C. to 500° C., 60° C. to 500° C., 70° C. to 500° C., 80° C. to 500° C., 90° C. to 500° C., 100° C. to 500° C., 200° C. to 500° C., 300° C. to 500° C., or 400° C. to 500° C. In some embodiments, the component is exposed for a pulse duration of 0.1 s to 4 s, 0.1 s to 3 s, 0.1 s to 2 s, 0.1 s to 1 s, 0.1 s to 0.9 s, 0.1 s to 0.8 s, 0.1 s to 0.7 s, 0.1 s to 0.6 s, 0.1 s to 0.5 s, 0.1 s to 0.4 s, 0.1 s to 0.3 s, 0.1 s to 0.2 s, 0.2 s to 5 s, 0.3 s to 5 s, 0.4 s to 5 s, 0.5 s to 5 s, 0.6 s to 5 s, 0.7 s to 5 s, 0.8 s to 5 s, 0.9 s to 5 s, 1 s to 5 s, 2 s to 5 s, 3 s to 5 s, or 4 s to 5 s.

In some embodiments, the aluminum oxide of the inner aluminum oxide layer acts as catalyst for the formation of the silicon oxide layer. In some embodiments, only a monolayer is needed to catalyze the silicon oxide growth. Table 1 shows how the thickness of the silicon oxide layer is strongly dependent on the delivery of the silicon precursor with the silicon precursor being tris(tert-pentoxy)silanol (TTOPSI), the aluminum precursor being trimethyl aluminum (TMA), and the reactor temperature for the ALD process being 150° C.

TABLE 1

| TMA^{a} pulse | TTOPSI^{b} Temp | | TTOPSI Pulse | | SiO₂ thickness | |
|---|---|---|---|---|---|---|
| 0.5 s | 55° | C. | 50 | s | 15 | Å |
| 0.5 s | 65° | C. | 50 | s | 20 | Å |
| 0.5 s | 90° | C. | 200 | s | 35 | Å |
| 0.5 s | 90° | C. | 400 | s | 43 | Å |
| 0.5 s | 95° | C. | 200 | s | 58 | Å |
| 0.5 s | 100° | C. | 150 | s | 83 | Å |

In some embodiments, the oxide layer and the aluminum oxide layer form a coating. In some embodiments, when the coating is formed of more than two layers, the process is repeated alternating between the process for the oxide layer and the process for the aluminum oxide layer until the desired number of layers is reached, up to 1000 layers.

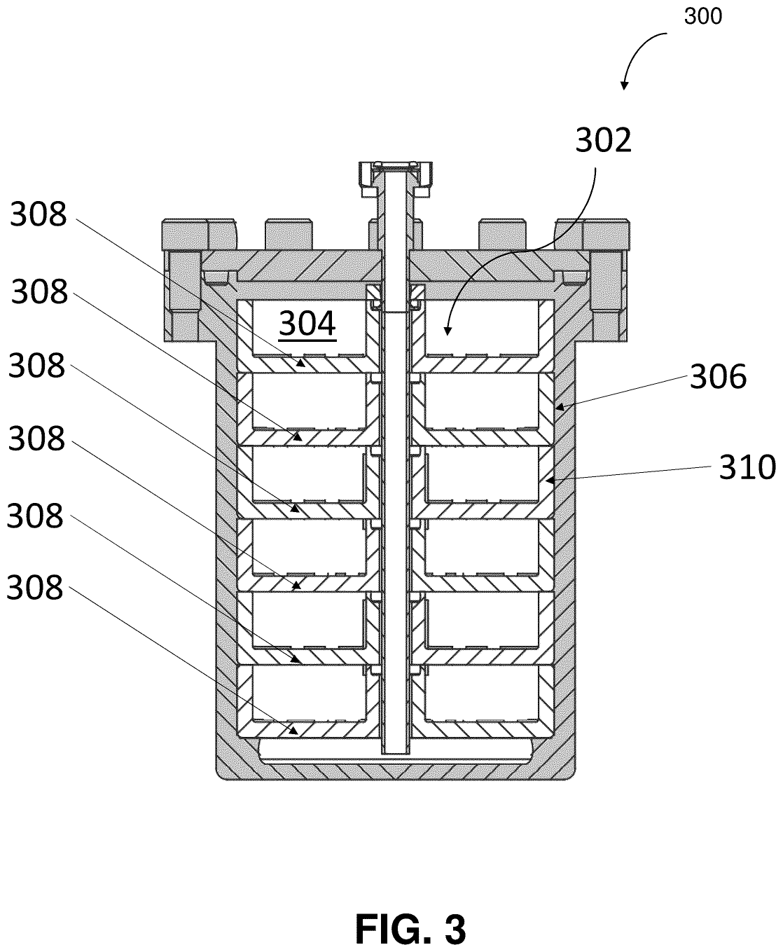

In some embodiments, the component can be a part of a vessel assembly. FIG. 3 is a schematic diagram of a cross-section of a vessel assembly, according to some embodiments. The vessel 300 contains a tray assembly 302 in an interior volume 304 of the vessel 300. The interior volume 304 has an inner wall surface 306. The tray assembly 302 comprises trays 308, each of which are configured to contain a vaporizable precursor. Each of the trays 308 of the tray assembly 302 comprises a portion 310 which is configured to be in contact (e.g., thermal contact, physical contact, etc.) with the inner wall surface 306 of the vessel 300. The surface-to-surface contact of the portion 310 with the inner wall surface 306 enhances heat transfer from the vessel 300 to each tray 308 and thus from each tray 308 to the vaporizable precursor on each tray 308. Various fluid flow paths are defined within the interior volume 304 of the vessel 300 such that a fluid is optionally allowed to flow through the vessel 300 upwards, downwards, or both. The vessel 300 is shown having a generally cylindrical inner chamber. However, it will be appreciated that the interior volume 304 of the ampoule may have other shapes without departing from the scope of this disclosure. In some embodiments, the composite coating can be applied to any part of the vessel described herein.

Some embodiments relate to a coating. In some embodiments, the coating comprises an inner aluminum oxide layer. In some embodiments, the inner aluminum oxide layer comprises an aluminum oxide of the formula: Al₂O_{y}, where y is 2.5 to 3.5. In some embodiments, the inner aluminum oxide layer has a thickness of 10 Å to 100 Å, or any range or subrange between 10 Å and 100 Å. In some embodiments, the inner aluminum oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the coating comprises a composite. In some embodiments, the composite comprises a first oxide layer and a second oxide layer. In some embodiments, the second oxide layer is different than the first oxide layer. In some embodiments, the second oxide layer is located on the first oxide layer. In some embodiments, the first oxide layer is located on the inner aluminum oxide layer.

In some embodiments, the first oxide layer comprises a silicon oxide layer. In some embodiments, the first oxide layer comprises a silicon dioxide of the formula: SiₓO_{y}, where x is 1 to 2 and y is 1.8 to 2.5. In some embodiments, the first oxide layer has a thickness of 10 Å to 100 Å, or any range or subrange between 10 Å and 100 Å. In some embodiments, the first oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the second oxide layer comprises an aluminum oxide layer. In some embodiments, the second oxide layer comprises an aluminum oxide of the formula: Al₂O_{y}, where y is 2.5 to 3.5. In some embodiments, the second oxide layer has a thickness of 10 Å to 100 Å, or any range or subrange between 10 Å and 100 Å. In some embodiments, the aluminum oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the composite comprises 2 to 1000 layers, 2 to 900 layers, 2 to 800 layers, 2 to 700 layers, 2 to 600 layers, 2 to 500 layers, 2 to 400 layers, 2 to 300 layers, 2 to 200 layers, 2 to 100 layers, 2 to 90 layers, 2 to 80 layers, 2 to 70 layers, 2 to 60 layers, 2 to 50 layers, 2 to 40 layers, 2 to 30 layers, 2 to 20 layers, 2 to 10 layers, 2 to 8 layers, 2 to 6 layers, 2 to 4 layers, 4 to 1000 layers, 6 to 1000 layers, 8 to 1000 layers, 10 to 1000 layers, 20 to 1000 layers, 30 to 1000 layers, 40 to 1000 layers, 50 to 1000 layers, 60 to 1000 layers, 70 to 1000 layers, 80 to 1000 layers, 90 to 1000 layers, 100 to 1000 layers, 200 to 1000 layers, 300 to 1000 layers, 400 to 1000 layers, 500 to 1000 layers, 600 to 1000 layers, 700 to 1000 layers, 800 to 1000 layers, or 900 to 1000 layers. In some embodiments, the layers of the composite alternate between being the first oxide layer and the second oxide layer. In some embodiments, the layers of the composite alternate between a silicon oxide layer and an aluminum oxide layer.

In some embodiments, the coating comprises an outer aluminum oxide layer. In some embodiments, the outer aluminum oxide layer is located on the composite. In some embodiments, the outer aluminum oxide layer comprises an aluminum oxide of the formula: Al₂O_{y}, where y is 2.5 to 3.5. In some embodiments, the outer aluminum oxide layer has a thickness of 10 Å to 100 Å, or any range or subrange between 10 Å and 100 Å. In some embodiments, the outer aluminum oxide layer has a thickness of 10 Å to 90 Å, 10 Å to 80 Å, 10 Å to 70 Å, 10 Å to 60 Å, 10 Å to 50 Å, 10 Å to 40 Å, 10 Å to 30 Å, 10 Å to 20 Å, 20 Å to 100 Å, 30 Å to 100 Å, 40 Å to 100 Å, 50 Å to 100 Å, 60 Å to 100 Å, 70 Å to 100 Å, 80 Å to 100 Å, or 90 Å to 100 Å.

In some embodiments, the inner aluminum oxide layer is located between a component and the composite. In some embodiments, when measured using Secondary Ion Mass Spectrometry (SIMS), the composite reduces a concentration of an impurity in the outer aluminum oxide layer by at least 10% compared to a control coating without the composite. In some embodiments, the composite reduces a concentration of an impurity in the outer aluminum oxide layer by at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 100% compared to a control coating without the composite.

In some embodiments, the impurity comprises at least one of iron, chromium, nickel, cobalt, molybdenum, manganese, vanadium, niobium, magnesium, titanium, copper, zinc, lead, aluminum, tin, or any combination thereof. In some embodiments, the impurity in the aluminum oxide layer comes from the component.

Any one or more of the embodiments disclosed herein shall be understood to be combinable without departing from the scope or spirit of the disclosure.

### Example 1

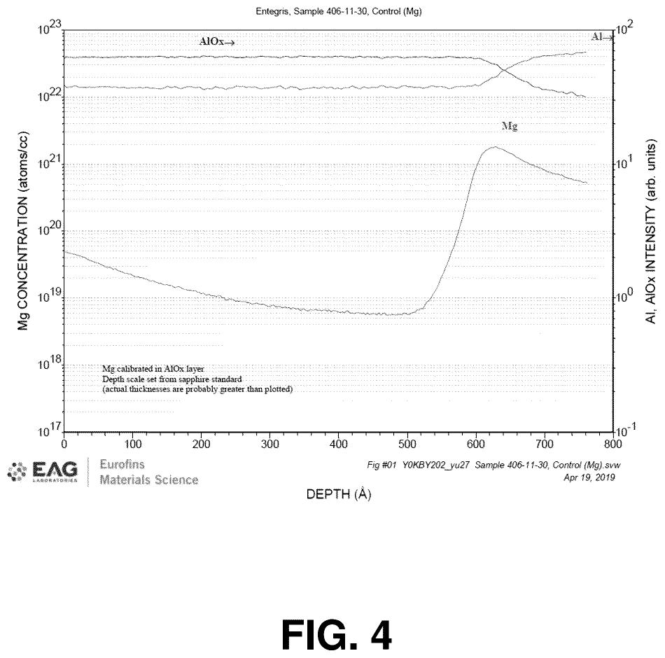

A layer of aluminum oxide (Al₂O_{y}) was deposited on a surface of a component. The component contained aluminum (Al) and magnesium (Mg). Using Secondary Ion Mass Spectrometry, the concentration of Mg was measured from the surface of the aluminum oxide layer to a depth of 800 Å. As can be seen in FIG. 4, the concentration of Mg increases near the surface of the aluminum oxide layer, creating impurities at the surface. If these components are used in semiconductor process hardware, the impurities may react with process chemicals to deliver undesirable contaminants downstream to a silicon wafer.

### Example 2

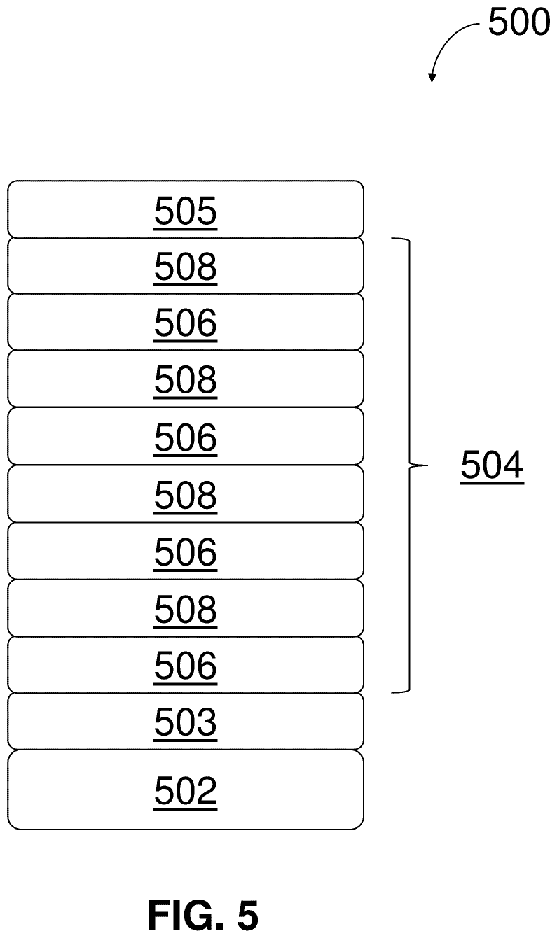

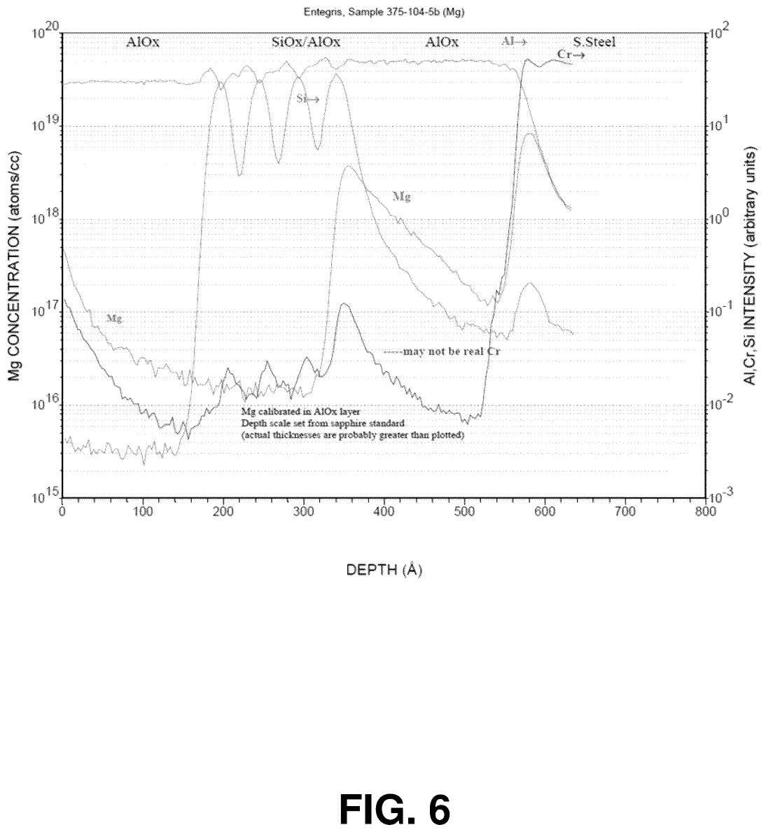

An inner layer of aluminum oxide (Al₂O_{y}) was deposited on a component, followed by a composite of the structure SiO_{y}/Al₂O_{y}/SiO_{y}/Al₂O_{y}/SiO_{y}/Al₂O_{y}/SiO_{y}/Al₂O_{y}, and finally an outer layer of aluminum oxide (Al₂O_{y}) was deposited on the composite to form a coating on the component, according to some embodiments. A depiction of the coating on a component 500 is shown in FIG. 5. In FIG. 5, 502 is the substrate, 503 is the inner aluminum oxide layer, 504 is the composite, and 505 is the outer aluminum oxide layer. Additionally, in the composite 504, the silicon oxide layers 506 alternate with the aluminum oxide layers 508. The component was a stainless steel alloy containing iron (Fe) and magnesium (Mg). Using Secondary Ion Mass Spectrometry, the concentration of Mg was measured from the surface of the outer aluminum oxide layer to a depth of 800 Å. As can be seen in FIG. 6, the use of the composite significantly reduces the amount of Mg present at the surface of the outer aluminum oxide layer.

### ASPECTS

Various Aspects are described below. It is to be understood that any one or more of the features recited in the following Aspect(s) can be combined with any one or more other Aspect(s).

Aspect 1. A coating comprising:
an oxide layer; and
an aluminum oxide layer;
   wherein the aluminum oxide layer is different than the oxide layer;
   wherein the oxide layer is located between a component and the aluminum oxide layer; and
   wherein, when measured using Secondary Ion Mass Spectrometry (SIMS), the oxide layer and the aluminum oxide layer reduce a concentration of an impurity in the aluminum oxide layer by at least 10% compared to a control coating without the oxide layer.

Aspect 2. The coating according to Aspect 1, wherein the component comprises a substrate, a vessel, a tray, a cabinet, a conduit, an ampoule, a chamber, a pipe, a valve, or any combination thereof.

Aspect 3. The coating according to any one of Aspects 1-2, wherein the component comprises an aluminum alloy, a nickel alloy, a stainless steel, a cobalt alloy, a titanium alloy, or any combination thereof.

Aspect 4. The coating according to any one of Aspects 1-3, wherein the impurity comprises at least one of an iron, a chromium, a nickel, a cobalt, a molybdenum, a manganese, a vanadium, a niobium, a magnesium, a titanium, a copper, a zinc, a lead, an aluminum, a tin, or any combination thereof.

Aspect 5. The coating according to any one of Aspects 1-4, wherein the oxide layer comprises a silicon oxide.

Aspect 6. The coating according to any one of Aspects 1-5, further comprising an aluminum oxide layer located between the component and the oxide layer.

Aspect 7. The coating according to any one of Aspects 1-6, wherein the oxide layer has a thickness of 10 Å to 100 Å.

Aspect 8. The coating of according to any one of Aspects 1-7, wherein the aluminum oxide layer has a thickness of 10 Å to 500 Å.

Aspect 9. The coating according to any one of Aspects 1-8, wherein, when measured using Secondary Ion Mass Spectrometry (SIMS), the oxide layer and the aluminum oxide layer reduce a concentration of the impurity in the aluminum oxide layer by at least 50% compared to a control coating without the oxide layer.

Aspect 10. The coating according to any one of Aspects 1-9, wherein the oxide layer comprises multiple oxide layers.

Aspect 11. A method comprising:
obtaining a component;
exposing the component to at least a first precursor to form an oxide layer on a surface of the component;
exposing the oxide layer to at least an aluminum precursor and a coreactant to form an aluminum oxide layer on the oxide layer,
   wherein the aluminum oxide layer is different than the oxide layer;
   wherein, when measured using Secondary Ion Mass Spectrometry (SIMS), the oxide layer and the aluminum oxide layer reduce a concentration of an impurity in the aluminum oxide layer by at least 10% compared to a control without the oxide layer.

Aspect 12. The method according to Aspect 11, wherein the component comprises a substrate, a vessel, a tray, a cabinet, a conduit, an ampoule, a chamber, a pipe, a valve, or any combination thereof.

Aspect 13. The method according to any one of Aspects 11-12, wherein the exposing the component to at least the first precursor proceeds at a temperature of 25° C. to 500° C. and for a pulse duration of 0.1 s to 500 s.

Aspect 14. The method according to any one of Aspects 11-13, wherein the exposing the oxide layer to at least the aluminum precursor and the coreactant proceeds at a temperature of 25° C. to 500° C.

Aspect 15. The method according to any one of Aspects 11-14, wherein the aluminum precursor comprises at least one of a trimethyl aluminum (TMA), a triethyl aluminum (TEA), a triisobutylaluminum (TIBA), a diethylaluminum chloride (DEAC), a methylaluminooxane (MAO), a dimethylaluminum isopropoxide (DMAI), an aluminum trichloride, or any combination thereof.

Aspect 16. The method according to any one of Aspects 11-15, wherein the first precursor comprises at least one of a tris(methoxy)silanol, a tris(ethoxy)silanol, a tris(tert-butoxy)silanol, a tris(tert-pentoxy)silanol, a bis(tert-butylamino)silane, a bis(diethylamino)silane, a bis(trichlorosilyl)ethane, a di(isopropylamino)silane, or any combination thereof.

Aspect 17. The method according to any one of Aspects 11-16, wherein the oxide layer comprises a silicon oxide.

Aspect 18. A coating comprising:
an inner aluminum oxide layer;
a composite comprising:
   a first oxide layer; and
   a second oxide layer,
      wherein the second oxide layer is different than the first oxide layer;
      wherein the second oxide layer is located on the first oxide layer;
      wherein the first oxide layer is located on the inner aluminum oxide layer; and
an outer aluminum oxide layer,
   wherein the outer aluminum oxide layer is located on the composite;
   wherein the inner aluminum oxide layer is located between a component and the composite; and
   wherein, when measured using Secondary Ion Mass Spectrometry (SIMS), the composite reduces a concentration of an impurity in the outer aluminum oxide layer by at least 10% compared to a control coating without the composite.

Aspect 19. The coating according to Aspect 19, wherein the composite comprises 3 to 1000 oxide layers.

Aspect 20. A method comprising:
forming an inner aluminum oxide layer on a component;
forming a composite on the inner aluminum oxide layer,
   wherein the composite comprises:
      a first layer comprising a silicon oxide; and
      a second layer comprising an aluminum oxide;
         wherein the first layer is located between the inner aluminum oxide layer and the second layer; and
forming an outer aluminum oxide layer on the composite,
   wherein, when measured using Secondary Ion Mass Spectrometry (SIMS), the composite reduces a concentration of an impurity in the outer aluminum oxide layer by at least 10% compared to a control without the composite.

What is claimed is:

1. A coating comprising:
an oxide layer; and
an aluminum oxide layer;
wherein the aluminum oxide layer is different than the oxide layer;
wherein the oxide layer is located between a component and the aluminum oxide layer; and
wherein, when measured using Secondary Ion Mass Spectrometry (SIMS), the oxide layer and the aluminum oxide layer reduce a concentration of an impurity in the aluminum oxide layer by at least 10% compared to a control coating without the oxide layer.

2. The coating of claim 1, wherein the component comprises a substrate, a vessel, a tray, a cabinet, a conduit, an ampoule, a chamber, a pipe, a valve, or any combination thereof.

3. The coating of claim 1, wherein the component comprises an aluminum alloy, a nickel alloy, a stainless steel, a cobalt alloy, a titanium alloy, or any combination thereof.

4. The coating of claim 1, wherein the impurity comprises at least one of an iron, a chromium, a nickel, a cobalt, a molybdenum, a manganese, a vanadium, a niobium, a magnesium, a titanium, a copper, a zinc, a lead, an aluminum, a tin, or any combination thereof.

5. The coating of claim 1, wherein the oxide layer comprises a silicon oxide.

6. The coating of claim 1, further comprising an aluminum oxide layer located between the component and the oxide layer.

7. The coating of claim 1, wherein the oxide layer has a thickness of 10 Å to 100 Å.

8. The coating of claim 1, wherein the aluminum oxide layer has a thickness of 10 Å to 500 Å.

9. The coating of claim 1, wherein, when measured using Secondary Ion Mass Spectrometry (SIMS), the oxide layer and the aluminum oxide layer reduce a concentration of the impurity in the aluminum oxide layer by at least 50% compared to a control coating without the oxide layer.

10. The coating of claim 1, wherein the oxide layer comprises multiple oxide layers.

11. A method comprising:
obtaining a component;
exposing the component to at least a first precursor to form an oxide layer on a surface of the component;
exposing the oxide layer to at least an aluminum precursor and a coreactant to form an aluminum oxide layer on the oxide layer,
wherein the aluminum oxide layer is different than the oxide layer;
wherein, when measured using Secondary Ion Mass Spectrometry (SIMS), the oxide layer and the aluminum oxide layer reduce a concentration of an impurity in the aluminum oxide layer by at least 10% compared to a control without the oxide layer.

12. The method of claim 11, wherein the component comprises a substrate, a vessel, a tray, a cabinet, a conduit, an ampoule, a chamber, a pipe, a valve, or any combination thereof.

13. The method of claim 11, wherein the exposing the component to at least the first precursor proceeds at a temperature of 25° C. to 500° C. and for a pulse duration of 0.1 s to 500 s.

14. The method of claim 11, wherein the exposing the oxide layer to at least the aluminum precursor and the coreactant proceeds at a temperature of 25° C. to 500° C.

15. The method of claim 11, wherein the aluminum precursor comprises at least one of a trimethyl aluminum (TMA), a triethyl aluminum (TEA), a triisobutylaluminum (TIBA), a diethylaluminum chloride (DEAC), a methylaluminooxane (MAO), a dimethylaluminum isopropoxide (DMAI), an aluminum trichloride, or any combination thereof.

16. The method of claim 11, wherein the first precursor comprises at least one of a tris(methoxy)silanol, a tris(ethoxy)silanol, a tris(tert-butoxy)silanol, a tris(tert-pentoxy)silanol, a bis(tert-butylamino)silane, a bis(diethylamino)silane, a bis(trichlorosilyl)ethane, a di(isopropylamino)silane, or any combination thereof.

17. The method of claim 11, wherein the oxide layer comprises a silicon oxide.

18. A coating comprising:
an inner aluminum oxide layer;
a composite comprising:
a first oxide layer; and
a second oxide layer,
wherein the second oxide layer is different than the first oxide layer;
wherein the second oxide layer is located on the first oxide layer;
wherein the first oxide layer is located on the inner aluminum oxide layer; and
an outer aluminum oxide layer,
wherein the outer aluminum oxide layer is located on the composite;
wherein the inner aluminum oxide layer is located between a component and the composite; and
wherein, when measured using Secondary Ion Mass Spectrometry (SIMS), the composite reduces a concentration of an impurity in the outer aluminum oxide layer by at least 10% compared to a control coating without the composite.

19. The coating of claim 18, wherein the composite comprises 3 to 1000 oxide layers.
